(19) United States
(12) Patent Application Publication
(10) Pub. No.: US 2006/0148148 A1
(43) Pub. Date: Jul. 6, 2006

(54) Semiconductor device manufacturing method

(76) Inventor: Tae Woo Kim, Icheon city (KR)

Correspondence Address: Song K. Jung;MCKENNA LONG & ALDRIDGE LLP, 1900 K Street, N.W., Washington, DC, 20006, US

(21) Appl. No.: 11/319,264

(22) Filed: Dec. 29, 2005

(30) Foreign Application Priority Data
Dec. 30, 2004 (KR) 10-2004-0116277

(51) Int. Cl. H01L 21/338; H01L 21/4763

(52) U.S. Cl. 438/185; 438/649

(57) ABSTRACT

A method of forming a semiconductor device in which a native oxide film is removed is disclosed. The native oxide film is initially formed by a damaging double ion implantation process. Thus, the method provides for the formation of a uniform salicidation layer, by forming regions where an ion implantation process is not performed at boundary regions between n-type transistors and p-type transistors. The method includes reflowing a first photoresist pattern to cover the pMOS areas, forming n-type source and drain regions using the first photoresist as a mask and performing an ion implantation process, reflowing a second photoresist to cover the NMOS areas, forming p-type source and drain regions using the second photoresist as a mask and performing an ion implantation process, depositing and applying heat to a metal layer to thereby form a salicidation layer in regions other than boundary regions of pMOS and nMOS areas.

This application claims the benefit of Korean Patent Application No. 10-2004-0116277, filed on Dec. 30, 2004, which is hereby incorporated by reference for all purposes as if fully set forth herein.

### BACKGROUND OF THE INVENTION

1. Field of the Invention

The present invention relates to semiconductor devices, and more particularly, to a semiconductor device manufacturing method which employs a photoresist reflowing process to prevent the occurrence of an unsalicided region between an n-type transistor and a p-type transistor.

2. Discussion of the Related Art

A CMOS device may have a pair of transistors, such as a pMOS transistor and an NMOS transistor, arranged adjacent to each other on a semiconductor substrate. To prevent short-channel effects, semiconductor devices including metal-oxide-semiconductor (MOS) transistors having a small channel length are provided with source/drain regions of both lightly doped and heavily doped drain regions formed on either side of a gate electrode. The transistor's channel length is determined by the spacing of the lightly doped drain regions, which are closer to the gate electrode than the heavily doped drain regions.

In manufacturing such a MOS transistor, gate electrodes are first formed on the semiconductor substrate. Lightly doped drain regions are then formed by performing an ion implantation process using the gate electrodes as a mask. Heavily doped drain regions are then formed by first forming spacers on the sidewalls of the gate electrodes and then performing an ion implantation process using the sidewall spacers formed on the gate electrodes as a mask. Thus, the more heavily doped drain regions have a lower contact resistance, while each of the lightly doped drain regions has a dopant concentration and a dopant depth less than a dopant concentration and a dopant depth in a corresponding heavily doped drain region. The above processes are respectively performed for each of the pMOS and NMOS transistors of the semiconductor device. Thereafter, the transistors are completed by forming one or more interlayer isolation films over the substrate surface, including the gate electrodes and the source/drain electrodes, and by constructing necessary logic circuitry made of multiple layers of metal interconnections in contact with the heavily doped regions through the interlayer isolation films.

FIGS. 1A-1D illustrate a related art method of forming a semiconductor device.

Referring to FIG. 1A, a gate oxide film 17 and a polysilicon gate 18 are sequentially formed on a semiconductor substrate 11 in which an active device isolation layer (not shown) is formed. Using the polysilicon gate 18 as a mask, a blanket ion implantation process is performed to implant a low concentration of n-type impurities, thereby forming lightly doped drain regions 21.

Referring to FIG. 1B, a sidewall spacer 22 is formed on the lateral walls of the gate polysilicon 18 by first depositing an oxide film (not shown) on an entire surface of the semiconductor substrate 11. Then, an etch-back process is performed on the oxide film. Simultaneously, the exposed portion of the gate oxide film 17 is also etched away and gate electrodes are thus formed. Next, the entire surface of the semiconductor substrate 11 is coated with photoresist (not shown). The photoresist is patterned to form a first photoresist pattern 50, which exposes only the nMOS transistor region. N-type source and drain regions 23 are formed by implanting n-type impurity ions, such as arsenic, using the first photoresist pattern 50 as a mask.

Referring to FIG. 1C, after the first photoresist pattern 50 is stripped, the entire surface of the semiconductor substrate 11 is again coated with photoresist (not shown). The photoresist is patterned to form a second photoresist pattern 51, which exposes only the pMOS transistor region. P-type source and drain regions 24 are formed by implanting p-type impurity ions, such as boron, using the second photoresist pattern 51 as a mask.

Referring to FIG. 1D, after the second photoresist pattern 51 is stripped, a salicidation layer 30 is formed on upper surfaces of the gate electrodes and the source/drain regions. Salicidation is achieved by using a deposition method, such as sputtering, to deposit a metal having a high melting point, such as cobalt, on an entire surface of the semiconductor substrate 11. A heat-treatment process, such as annealing, is performed on the deposited material. Excess metal material is then removed from the surface of the semiconductor substrate 11 by a cleaning process performed after heat-treatment process.

In the related art process, however, there is unavoidably some degree of misalignment in forming the first and second photoresist patterns 50 and 51. This causes both n-type and p-type impurity implantation to occur in and along a boundary region between the nMOS and pMOS transistors. This boundary region, which may be about 0.50 μm in width or may extend over about 0.25 μm of each region of the adjacently arranged pair of MOS transistors, is thus subjected to two ion implantations. Thus, the deposited metal, such as cobalt, is not subjected to a salicidation reaction with the source/drain regions along the boundary region. This boundary region is therefore an unsalicided region. Therefore, instead of forming a salicidation layer during the heat treatment process in the boundary region, a native oxide film 90 is formed and occupies the boundary region. The doubly performed ion implantation damages the boundary region, and the damage results in the generation of the native oxide 90 during the heat treatment process. The native oxide film 90 cannot be completely removed during the successive cleaning process.

Accordingly, the native oxide film 90, which has an inherent insulating characteristic, is present in the boundary regions where both the p-type and n-type impurity ions are implanted. As a result, the resistance of the salicidation layer increases.

### SUMMARY OF THE INVENTION

Accordingly, the present invention is directed to a semiconductor device manufacturing method that substantially obviates one or more of the problems due to limitations and disadvantages of the related art.

An advantage of the present invention is to provide a semiconductor device manufacturing method, which prevents the formation of a native oxide film that occurs when a double ion implantation is performed in adjacently arranged pMOS and nMOS transistors.

Another advantage of the present invention is to provide a semiconductor device manufacturing method in which a uniform salicidation layer is formed across a boundary region between adjacently arranged pMOS and nMOS transistors.

Another advantage of the present invention is to provide a semiconductor device manufacturing method, which prevents the occurrence of a double ion implantation phenomenon along a boundary region between adjacently arranged pMOS and nMOS transistors.

Another advantage of the present invention is to provide a semiconductor device manufacturing method, which prevents an ion implantation along a boundary region between an n-type transistor and a p-type transistor, by employing a photoresist reflow process when respectively masking n-type and p-type source/drain regions.

Additional features and advantages of the invention will be set forth in the description which follows, and in part will be apparent from the description, or may be learned by practice of the invention. The objectives and other advantages of the invention will be realized and attained by the method particularly pointed out in the written description and claims hereof as well as the appended drawings.

To achieve these and other advantages and in accordance with the purpose of the present invention, as embodied and broadly described, there is provided a method of forming a semiconductor device comprising forming an element isolating layer in a semiconductor substrate on which pMOS areas and nMOS areas are defined; forming a gate electrode by forming and patterning a polysilicon layer on the semiconductor substrate; forming sidewall spacers on both sidewalls of the gate electrode; forming and flowing a first photoresist pattern to cover the pMOS areas; forming an n-type source and drain regions using the first photoresist as a mask and performing an ion implantation process with a high concentration of impurities; forming and flowing a second photoresist to cover the NMOS areas; forming a p-type source and drain regions using the second photoresist as a mask and performing an ion implantation process with a high concentration of impurities; and forming a salicidation layer in the regions other than boundary regions of the pMOS areas and the NMOS areas by depositing a metal layer on the entire surface of the semiconductor substrate and applying heat thereto.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principle of the invention. In the drawings:

FIGS. 1A-1D are cross-sectional views of a pair of transistors of a CMOS device illustrating a related art method; and

FIGS. 2A-2F are cross-sectional views of a pair of transistors of a CMOS device illustrating a method according to the present invention.

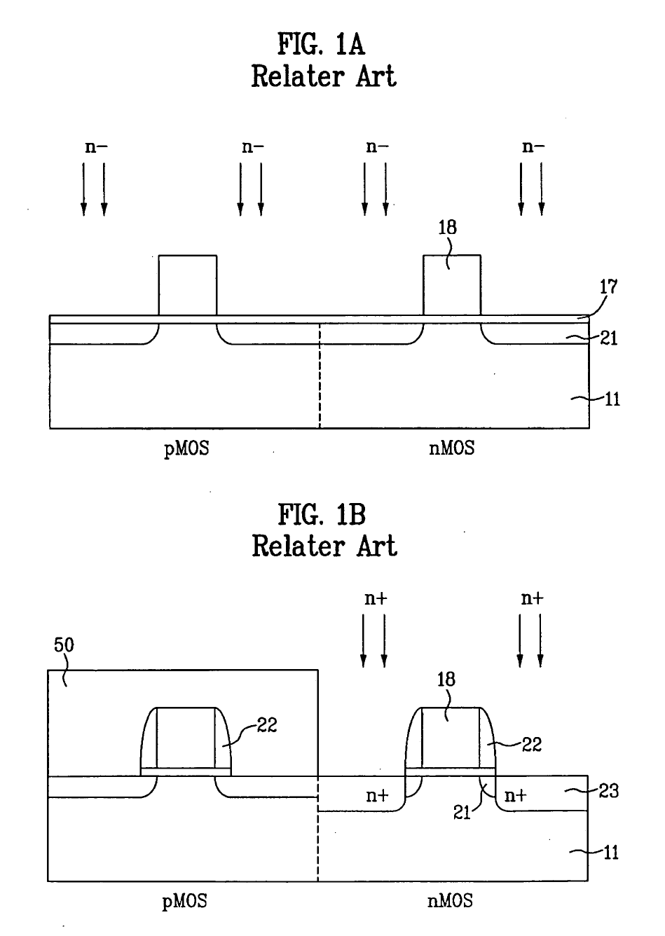

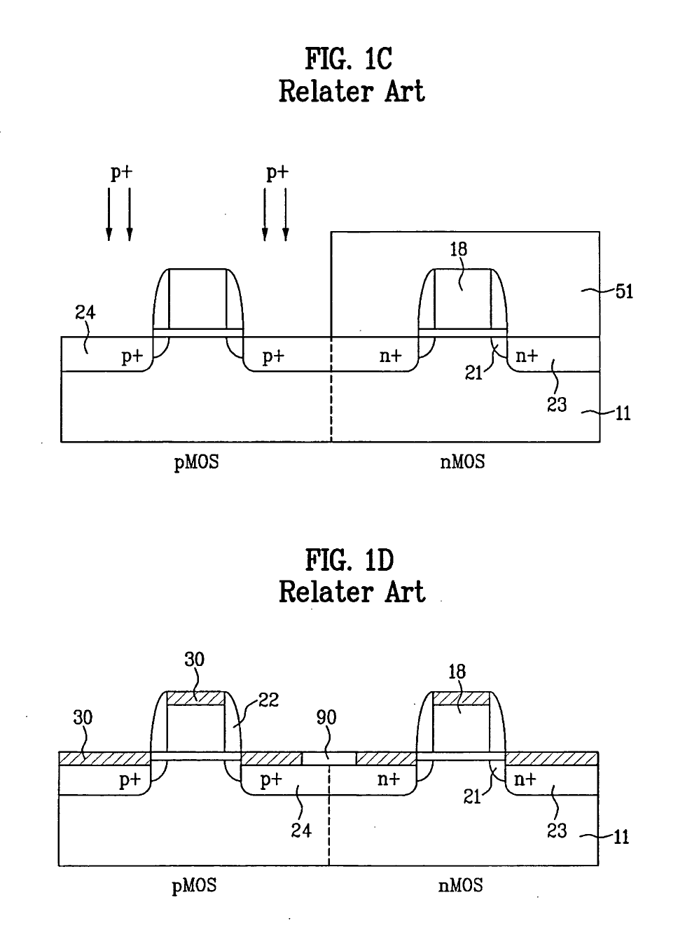

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

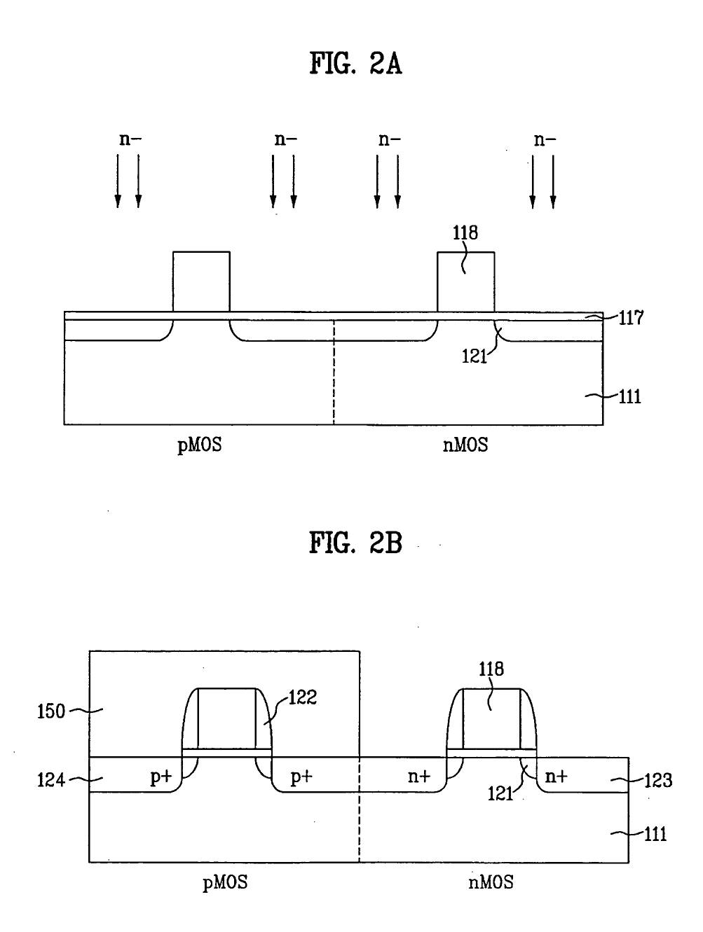

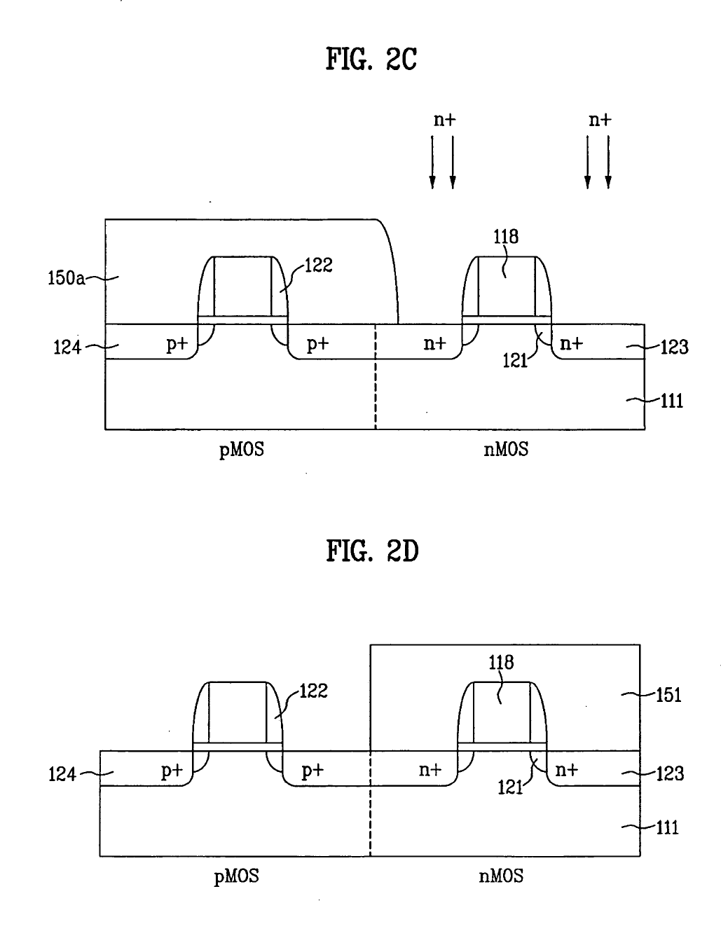

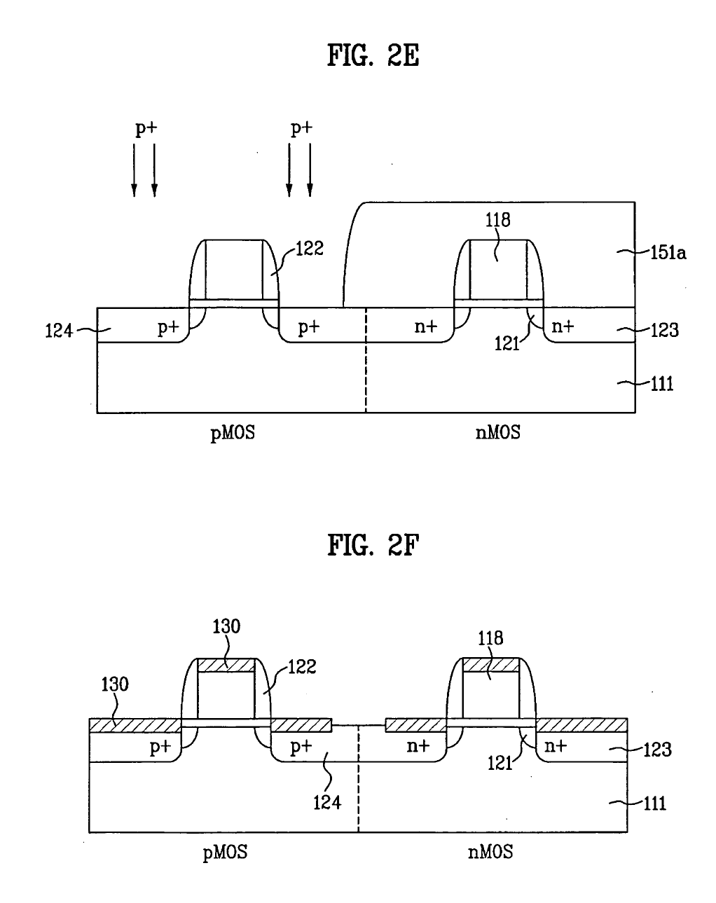

Referring to FIG. 2A, a gate oxide film 117 and a polysilicon gate 118 are sequentially formed on a semiconductor substrate 111. The semiconductor substrate 111 may include an active device isolation layer (not shown) formed by anisotropically etching a p-type substrate to form a trench, filling the trench by depositing an insulating film, and then planarizing the resultant structure to form an n-type well corresponding to active regions. A gate may be a single film of polysilicon, i.e., gate poly, or a stacked structure made of polysilicon and a metal layer having very low resistance. The metal layer may include a diffusion preventing film and a tungsten or tungsten silicide film. Using the polysilicon gate 118 as a mask, an ion implantation process is performed to implant a low concentration of n-type impurities, thereby forming lightly doped drain regions 121.

Referring to FIG. 2B, a sidewall spacer 122 is formed on the lateral walls of the gate polysilicon 118 by first depositing an oxide film (not shown) on and entire surface of the semiconductor substrate 111 and then performing an etch-back process. The exposed portion of the gate oxide film 117 is also etched away and gate electrodes are formed. Then, the entire surface of the semiconductor substrate 111 is coated with photoresist (not shown). The photoresist is patterned to form a first photoresist pattern 150 exposing only an nMOS transistor region.

As shown in FIG. 2C, the first photoresist pattern 150 is reflowed to form reflowed first photoresist pattern 150a. The reflowing process causes the first photoresist pattern 150 to flow towards n-type transistors from the boundaries between n-type and p-type transistors. Then, n-type source and drain regions 123 are formed by implanting n-type impurity ions such as phosphorus and arsenic. Reflowing the first photoresist pattern 150 may be performed at a temperature of approximately 120-150° C.

Thus, n-type impurity ions are not implanted into n-type transistor regions around boundaries between n-type and p-type transistors. The regions into which n-type impurity ions are not implanted include p-type transistor regions and n-type transistor regions spaced apart by a distance of approximately 0.25-0.30 μm from the boundaries between the n-type and p-type transistors.

Thereafter, after the first photoresist pattern 150 is stripped, as shown in FIG. 2D, a second photoresist is coated on an entire surface of the semiconductor substrate 111 to form second photoresist pattern 151. The second photoresist 151 is patterned to be opened only to pMOS transistor regions.

As shown in FIG. 2E, the second photoresist pattern 151 is reflowed to form reflowed second photoresist pattern 151a. The reflowing process causes the second photoresist pattern 151 to flow towards p-type transistors from the boundaries between the n-type and p-type transistors. Then, p-type source and drain regions 124 are formed by implanting n-type impurity ions such as boron. Reflowing the second photoresist pattern 151 may be performed at a temperature of approximately 120-150° C.

Thus, p-type impurity ions are not implanted into p-type transistor regions around boundaries between n-type and p-type transistors. The regions into which p-type impurity ions are not implanted include n-type transistor regions and p-type transistor regions spaced apart by a distance of approximately 0.25-0.301 μm from the boundaries between the n-type and p-type transistors.

Therefore, n-type source and drain regions 123 and p-type source and drain regions 124 are formed. Regions having a width of approximately 0.5-0.6 μm into which impurity ions are not implanted are formed in the boundaries between n-type and p-type transistors.

Next, after the second photoresist 151 is stripped, as shown in FIG. 2F, a high melting metal such as cobalt is evaporated and heat treated on an entire surface of the semiconductor substrate 111. Thus, a salicidation layer 130 is formed on surfaces of the polysilicon gate 118, the n-type source and drain regions 123, and the p-type source and drain regions 124. The salicidation layer 130 is not formed at the boundaries between the n-type and p-type transistors into which impurity ions are not implanted. Thus, a surface of the semiconductor substrate 111 or the polysilicon gate 118 is exposed at the boundaries between the n-type and p-type transistors into which impurity ions are not implanted. The semiconductor substrate 111 may be made of silicon.

Therefore, the boundary region of the n-type and p-type transistors having an insulating characteristic due to the existence of a native oxide film is changed to form regions having a conductive characteristic by the polysilicon gate or a silicon substrate. As a result, increased resistance of the salicidation layer is prevented.

The regions in which an ion implantation process is not performed are formed in the boundary regions between n-type MOS and p-type MOS transistors using a photoresist reflow process. The reflow process is performed when n-type and p-type source and drain regions are masked. Thus, a native oxide film formed by a damaging double ion implantation process is removed and a uniform salicidation layer is formed.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A method of forming a semiconductor device, the method comprising:
forming an element isolating layer in a semiconductor substrate on which pMOS areas and nMOS areas are defined;
forming and reflowing a first photoresist pattern to cover the pMOS areas;
forming n-type source and drain regions using the first photoresist pattern as a mask and performing an ion implantation process;
forming and reflowing a second photoresist pattern to cover the NMOS areas;
forming p-type source and drain regions using the second photoresist pattern as a mask and performing an ion implantation process;
depositing a metal layer on an entire surface of the semiconductor substrate; and
applying heat to the metal layer, to thereby form a salicidation layer in regions other than boundary regions between the pMOS areas and the NMOS areas.

2. The method according to claim 1, wherein the first and second photoresist patterns are reflowed at a temperature of approximately 120-150° C.

3. The method according to claim 1, wherein the first and second photoresist patterns are reflowed to be spaced apart by a distance of approximately 0.25-0.30 μm from the boundary regions between the nMOS areas and the pMOS areas.

4. The method according to claim 1, wherein regions in which the salicidation layer is not formed in the boundary regions between the nMOS areas and the pMOS areas have a width of approximately 0.5-0.6 μm.

5. The method according to claim 1, further comprising forming LDD regions by performing an ion implantation process with a low concentration of impurities.

6. The method according to claim 1, further comprising:
forming and patterning a polysilicon layer on the semiconductor substrate to form a gate electrode; and
forming sidewall spacers on both sidewalls of the gate electrode.

7. The method according to claim 1, wherein both ion implantation processes are performed with a high concentration of impurities.

8. The method according to claim 6, wherein both ion implantation processes are performed with a high concentration of impurities.

9. The method according to claim 8, wherein the first and second photoresist patterns are reflowed at a temperature of approximately 120-150° C.

10. The method according to claim 8, wherein the first and second photoresist patterns are reflowed to be spaced apart by a distance of approximately 0.25-0.30 μm from the boundary regions between the NMOS areas and the pMOS areas.

11. The method according to claim 8, wherein regions in which the salicidation layer is not formed in the boundary regions between the nMOS areas and the pMOS areas have a width of approximately 0.5-0.61 μm.

12. The method according to claim 8, wherein after forming the gate electrode, LDD regions are formed by performing an ion implantation process with a low concentration of impurities using the gate electrode as a mask.
